(19) United States
(12) Patent Application Publication
(10) Pub. No.: US 2024/0250196 A1
(43) Pub. Date: Jul. 25, 2024

(54) SOLAR-CELL MODULE

(71) Applicant: Fraunhofer-Gesellschaft zur Förderung der angewandten Forschung e.V., München (DE)

(72) Inventors: Sebastian NEVEN-DU MONT, Freiburg (DE); Martin HEINRICH, Freiburg (DE)

(73) Assignee: Fraunhofer-Gesellschaft zur Förderung der angewandten Forschung e.V., München (DE)

(21) Appl. No.: 18/562,490

(22) PCT Filed: May 6, 2022
(86) PCT No.: PCT/EP2022/062328

§ 371 Date: Nov. 20, 2023

(30) Foreign Application Priority Data
May 19, 2021 (DE) 10 2021 112 981.8

(51) Int. Cl. H01L 31/05; H02S 20/30

(52) U.S. Cl. CPC H01L 31/0504; H02S 20/30

(57) ABSTRACT

A solar cell module, having module segments, each with photovoltaic solar cells interconnected in series. The cells of the module segments are arranged on or in a curved planar carrier element. Each cell has a solar cell normal vector, and the module has a module normal vector, corresponding to the vectorial mean value of the cell normal vectors. Each cell has a tilt angle, corresponding to the angle between the cell normal vector and the module normal vector. Each module segment is assigned a tilt angle range having limits defined by minimum and maximum tilt angles of the cells of the module segment. The tilt angle ranges of at least two module segments are disjoint. The module segments are interconnected in parallel, each module segment has the same number of cells, and each cell of a module segment is arranged directly adjacent to a further cell of that module segment.

### CROSS-REFERENCE TO RELATED APPLICATIONS

This application is a 371 National Phase of PCT/EP2022/062328, filed May 6, 2022, which claims priority to German Patent Application No. 10 2021 112 981.8, filed May 19, 2021, both of which are incorporated herein by reference as if fully set forth.

### TECHNICAL FIELD

The invention relates to a solar cell module.

### BACKGROUND

Solar cells are sensitive semiconductor components. In order to protect them from environmental influences with long-term resistance and achieve manageable electrical output parameters, solar cells are typically electrically interconnected and encapsulated in a module structure.

In typical solar modules, the solar cells are arranged on a flat planar carrier element and divided into multiple module segments. Each module segment typically has multiple solar cell strings (strings) interconnected in parallel. Each solar cell string has a plurality of photovoltaic solar cells interconnected in series.

Due to the worldwide upscaling of the production of solar cells, the production costs have significantly decreased, so that new applications also result for those areas which are not oriented optimally in relation to the sun and accordingly have a lower specific yield. Such areas are, for example, hoods and roofs of vehicles, in particular passenger vehicles, as well as building façades and building envelopes.

### SUMMARY

There is therefore a need to integrate solar cells into curved surfaces.

The present invention is therefore based on the object of providing a solar cell module which is suitable for arranging solar cells on or in curved carrier elements.

This object is achieved by a solar cell module having one or more of the features disclosed herein. Advantageous embodiments are found below and in the claims.

The invention is based on the finding that there are special requirements upon the typical use of solar cells and applications having curved surfaces:

The fundamental goal in the production of solar cell modules is an interconnection of the solar cells and the solar cell strings which enables simple production and is electrically safe and efficient. In particular, the occurrence of so-called hotspots in the event of partial shading is to be avoided: it is known that upon partial shading of a solar cell module, there is a risk that a large amount of heat generation will occur in shaded solar cells due to the operation of the (partially) shaded solar cell in the reverse range, which can negatively affect the integrity of the module up to destruction of the module. Furthermore, low ohmic losses are to occur upon the module interconnection and a low material expenditure is also advantageous.

If solar cells are used in areas of application having curved surfaces, the solar cell module has to have a two-dimensional or three-dimensional curvature. The module design once again becomes significantly more complex in this way. Different solar cells of the module have different orientations in relation to the incident sunlight due to a curvature. Since the charge carrier generation within the solar cells and thus the conversion of incident electromagnetic radiation into electrical energy is directly proportional to the incident intensity, a difference in the dimension of the generated current, a so-called current mismatch, arises upon a series interconnection of solar cells oriented differently in relation to the incident sunlight. The solar cell having the lowest current production limits the output of the entire string here. The same effect occurs upon the series interconnection of strings at different curvature positions in the solar cell module.

In contrast to the generated current of a solar cell, the generated voltage of a solar cell is significantly less dependent on the incident radiation intensity and in particular the orientation in relation to the incident sunlight. For this reason, inhomogeneous incident radiation on the solar cell due to a curvature of the solar cell module has a significantly less disadvantageous effect on the voltage of a string.

The invention is based in particular on the finding that for the design of a solar cell module having a curved surface, a series interconnection of solar cells having similar angles of inclination in relation to the incident sunlight and a parallel interconnection of solar cells having different angles of inclination in relation to the incident sunlight is advantageous.

The solar cell module according to the invention has at least one first, one second, and one third module segment. Each of the module segments has a plurality of photovoltaic solar cells interconnected in series.

It is essential that the solar cells of the module segments are arranged on or in a curved planar carrier element. Each solar cell is assigned a solar cell normal vector. The solar cell normal vector is thus a vector which is orthogonal to the plane formed by the surface of the solar cell. The solar cells have an essentially flat surface, so that the normal vector is unambiguously defined. The solar cells can also have slight curvatures, in this case the solar cell normal vector represents the spatial direction from which the maximum output power is achieved upon a radiation with sunlight. This is typically the vectorial mean value when individual planar areas of the solar cell are each assigned a normal vector.

A solar cell module normal vector, which corresponds to the vectorial mean value of the solar cell normal vectors, is assigned to the solar cell module. The direction of the solar cell module normal vector therefore represents a particularly advantageous direction of incidence for sunlight.

A tilt angle is assigned to each solar cell, which corresponds to the angle between the solar cell normal vector of the solar cell and the solar cell module normal vector.

A tilt angle range is assigned to each module segment, the limits of which are defined by the minimum and maximum tilt angles of the solar cells of the module segment.

It is essential that the tilt angle ranges of at least two module segments are disjoint, that the module segments are interconnected in parallel, that each module segment has the same number of solar cells, and that each solar cell of a module segment is arranged directly adjacent to at least one further solar cell of the same module segment.

Therefore, due to this design and arrangement of the solar cells and division into module segments, at least two module segments having disjoint tilt angle ranges are provided, these module segments are interconnected in parallel and each module segment has a plurality of photovoltaic solar cells interconnected in series. A current mismatch due to the different tilt angles, which in particular affects the amperage of the solar cell, as described above, is reduced by the parallel connection of the module segments.

Since each module segment has the same number of solar cells and different tilt angles have a significantly lesser effect on the output voltage of the solar cell in relation to the amperage, as described above, the differences of the overall voltage of the individual module segments are comparatively minor.

To avoid or at least reduce negative effects due to a current mismatch, it is advantageous for a large number of module segments to be formed. The solar cell module advantageously has at least five, at least eight, in particular at least 10, more preferably at least 20 module segments, wherein each module segment is designed according to the conditions mentioned above for the first, second, and third module segment.

Overall, it is advantageous for a large number of these disjoint angle ranges to be predetermined in order to reduce the current mismatch. The solar cell module therefore advantageously has at least three, in particular at least five, more preferably at least 10 module segments having disjoint angle ranges.

In order to achieve the most uniform possible overall voltage of all module segments, it is advantageous for all module segments of the solar cell module to have the same number of solar cells. A module segment preferably has at least two, preferably at least 3, more preferably at least 4, more preferably at least 8 solar cells.

To achieve the lowest possible current mismatch, it is advantageous for the solar cells of each module segment to be interconnected in series, i.e., to be interconnected in a series interconnection.

The module segments of the solar cell module according to the invention can have arbitrary geometrical shapes as such, which are predetermined by the arrangement of the solar cells of the solar cell module. In particular, it is within the scope of the invention that one or more of the module segments have a rectangular shape or an L shape.

The solar cells of the solar cell module are preferably arranged in a manner known per se so that the solar cells form a uniform arrangement within a rectangular border. In particular, the center points of the solar cells are preferably arranged on the grid lines of a uniform rectangular grid.

The division of the solar cell module into module segments as described above therefore allows the curvature of the solar cell module to be divided into multiple curvature ranges and one or more module segments to be assigned to each curvature range. In this case, it is particularly advantageous for the solar cell module to have a group of at least two module segments, in particular of four module segments, which includes at least one middle module segment, in particular two middle module segments.

A curvature in two spatial directions is approximated by such an arrangement.

The solar cells of the solar cell module can be designed in a manner known per se. In particular, solar cells contacted on both sides, which are known per se and which are connected by means of cell connectors that connect the front side of one solar cell to the rear side of an adjacent solar cell, can be interconnected in series. It is within the scope of the invention that square solar cells, solar cells having flattened corners (pseudosquare), or also rectangular solar cells having a length to width ratio greater than 1, in particular greater than 1.5, in particular greater than 2, can be used. In particular, the use of so-called partial solar cells, which result from the cell division of a starting solar cell, in particular a square starting solar cell, is within the scope of the invention.

The solar cell module according to the invention is suitable in particular for the use of silicon solar cells. However, it is also within the scope of the invention to use solar cells based on other semiconductor materials or based on a combination of multiple semiconductor materials to form the solar cell module according to the invention.

The use of solar cells that can be contacted on the rear side is particularly advantageous. Such solar cells have both at least one positive and one negative contacting point on the rear side, so that it is not necessary to contact the front side of the solar cell by means of a cell connector. Such solar cells are, for example, rear side contact solar cells, which do not have a metallic contacting structure on the front side. MWT (metal wrap through) structures are also known, in which an additional rear-side contacting option is formed by means of a metallic through connection from the front side to the rear side of the solar cell.

Solar cells that can be contacted on the rear side have the advantage that the series circuit of the solar cells within a solar cell segment and, in a further preferred embodiment, also the parallel interconnection of the module segments can be formed by means of cell connecting elements arranged on the rear side. In particular, the use of a flexible interconnection element which has electrically conductive tracks is advantageous. Such an interconnection element can be designed, for example, as a structured film coated with metal.

The division into module segments can be carried out as described hereinafter for a specified curved planar carrier element and a specified number and design of solar cells:

If, for example, the planar carrier element is specified as a roof of a passenger vehicle and solar cells which have a uniform width and length are specified, then the solar cells can be distributed as described above in a regular arrangement over the desired surface to be covered, so that the center point of each solar cell is arranged on the intersection point of a regular rectangular grid, which simulates the curved shape of the planar carrier element.

The arrangement of the solar cells on or in the curved planar carrier element specifies the inclination of the solar cells so that the solar cell module normal vector is defined by the vectorial mean value of the solar cell normal vectors and for each solar cell the tilt angle is defined as the angle between the solar cell module normal vector and the solar cell normal vector of the solar cell.

In one advantageous possible embodiment of the division of the solar cell module into module segments, a maximum deviation of the angle of inclination of a module segment is specified. The solar cells are now combined into groups, so that the number of the solar cells is maximized within each group, but the angle range of the group, i.e., the difference of the solar cell having the smallest and the largest tilt angle in the group, is not greater than the specified maximum angle range. The group having the smallest number of solar cells defines the total number of solar cells of the module segments. All groups are now divided according to this number such that each module segment has the defined number of solar cells. As described above, a module segment is in this case a congruent region, i.e., each solar cell of a module segment adjoins at least one further solar cell of the same module segment. Solar cells, the corners of which adjoin one another, are also considered adjoining cells.

The higher a desired yield of the curved module is specified, the smaller the maximum angle range has to be selected. It is therefore advantageous that each module segment has an angle span, i.e., the difference of the minimum and maximum tilt angle of the module segment, which is preferably less than or equal to 60°, more preferably less than or equal to 30°, in particular less than or equal to 15°. To achieve particularly high yields, it is advantageous for each module segment to have an angle span less than 12°, preferably less than 8°, particularly preferably less than 4°, in particular less than 2°.

### BRIEF DESCRIPTION OF THE DRAWINGS

Further advantageous features and embodiments will be explained hereinafter on the basis of exemplary embodiments and the figures.

FIGS. 1, 1A, and 1B show a first exemplary embodiment of a solar cell module according to the invention, with FIG. 1A schematically showing the division of the module segments and FIG. 1B showing a sectional representation to illustrate the curvature of the solar cell module and the tilt angles of the solar cells.

FIGS. 2 and 2A show a second exemplary embodiment of a solar cell module according to the invention.

FIGS. 3, 3A, and 3B show a third exemplary embodiment of a solar cell module according to the invention.

### DETAILED DESCRIPTION

All figures show schematic representations which are not to scale. Identical reference signs in the figures identify identical or identically acting elements.

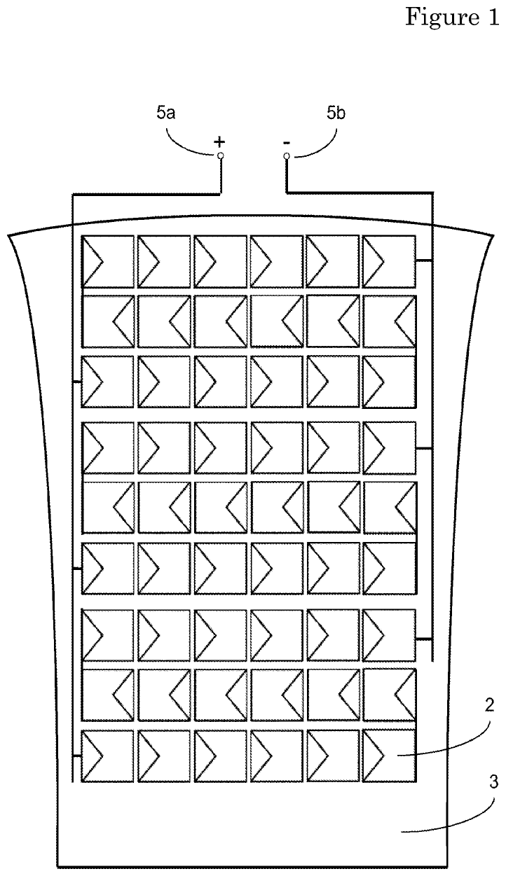

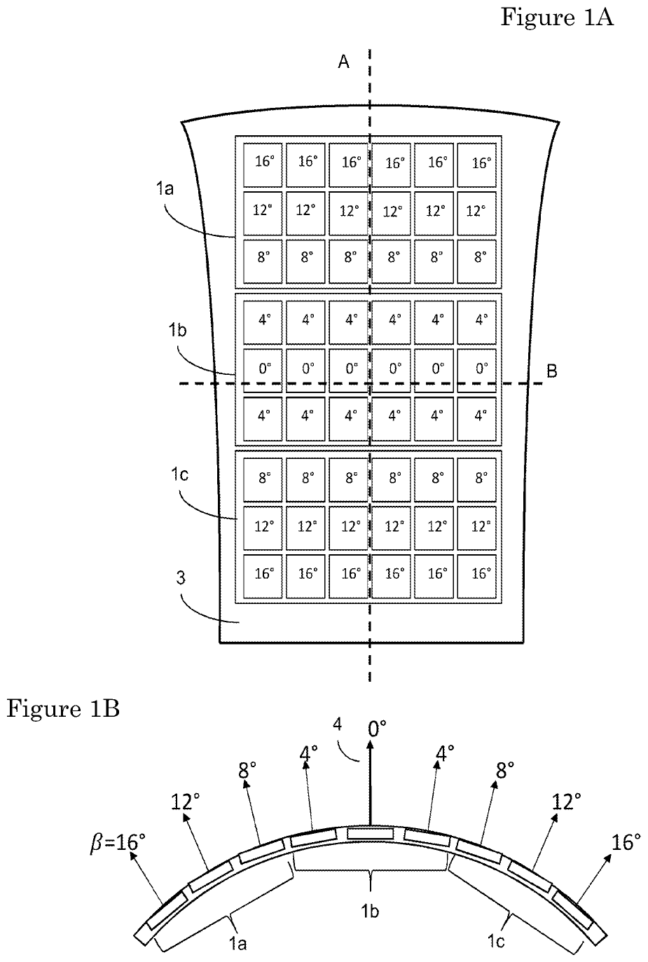

The solar cells are shown as rectangles in each case in FIGS. 1, 1A, 1B, 2, 2A, 3, #A, and 3B, wherein the transmission direction of the solar cell is identified by means of an arrow in each case.

The first exemplary embodiment of a solar cell module according to the invention shown in FIG. 1 has a first module segment 1a, a second module segment 1b, and a third module segment 1c. The division of the module segments is apparent in FIG. 1A.

Each of the three module segments has 18 photovoltaic solar cells interconnected in series. The solar cells are designed as silicon solar cells.

The solar cells of the module segments 1a, 1b, and 1c are arranged on a curved planar carrier element 3, and in the present case a roof of a passenger vehicle.

The carrier element 3 has a uniform curvature in only one spatial direction in the present case: in the illustration according to FIG. 1A, the carrier element 3 has a curvature having radius of curvature 1500 mm in the direction identified by A. In contrast, in the direction identified by B, the carrier element has no curvature.

In FIG. 1B, a section is shown through the solar cell module along line A according to FIG. 1A and perpendicular to the plane of the drawing having the curved transparent carrier element 3, in which the solar cells 2 are arranged. The normal vector, which is perpendicular to the surface of the solar cell, is shown as an arrow for each solar cell. The vectorial mean value of the solar cell normal vectors results in the solar cell module normal vector 4. In the present case, this corresponds to the solar cell normal vector of the mean solar cell, which accordingly has a tilt angle of 0°.

The angle between the solar cell module normal vector 4 and the solar cell normal vector of a solar cell results in the tilt angle of this solar cell. The tilt angles are indicated for each solar cell in each case above the solar cell normal vector.

As explained above, the carrier element 3 according to the first exemplary embodiment only has a uniform curvature in direction A according to FIG. 1A.

Accordingly, all solar cells of the first module segment 1a and the third module segment 1c have a tilt angle of 8°, 12∪, or 16°. The solar cells of the second module segment 1b have a tilt angle of 0° or 4°.

Therefore, tilt angle ranges of 8° to 16° are assigned to the first module segment 1a and the third module segment 1c. A tilt angle range of 0° to 4° is assigned to the second module segment 1b. The tilt angle range of the second module segment 1b is therefore disjoint to the tilt angle range of the first module segment 1a and the third module segment 1c.

As is apparent in FIG. 1, the positive pole of the first solar cell of a module segment is connected in each case to a positive connection pole 5a via conductor tracks. Accordingly, the negative pole of the last solar cell in the series circuit of each module segment is connected in each case to a negative connection pole 5b via conductor tracks. The three module segments 1a, b, and 1c are therefore interconnected in parallel.

Each module segment has the same number of solar cells, in the present case 18 solar cells. Each solar cell of a module segment is arranged directly adjacent to at least one further, in the present case to at least two further solar cells of the same module segment.

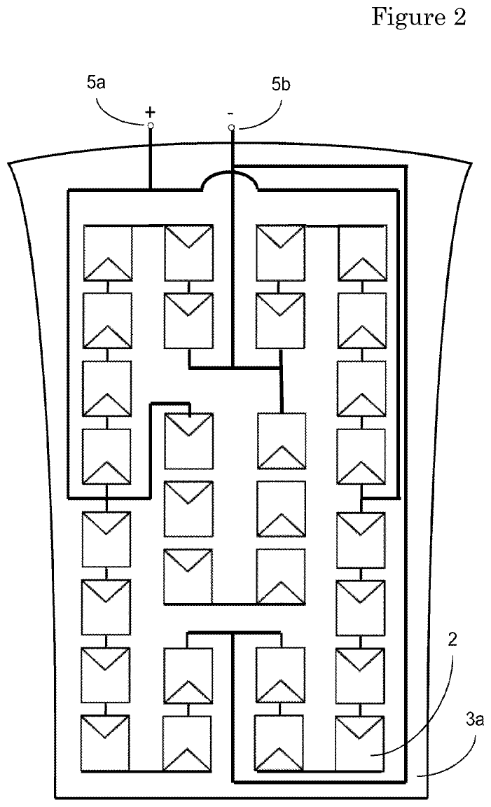

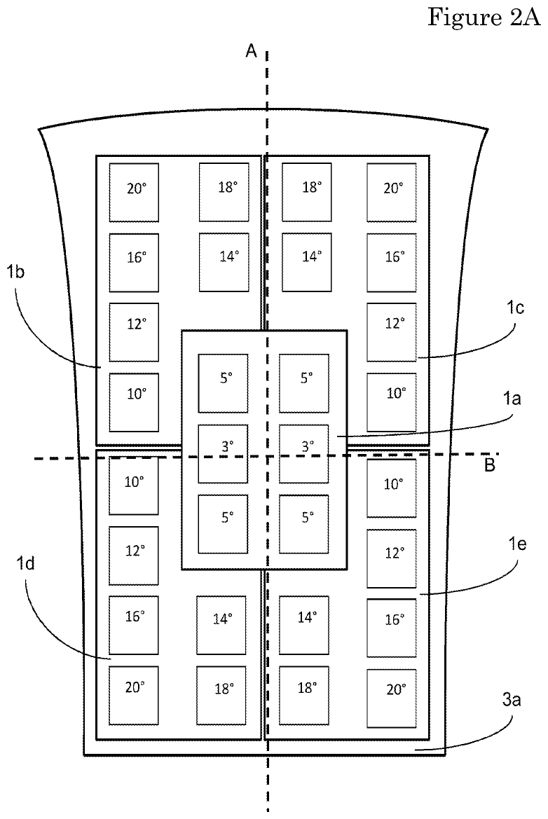

The second exemplary embodiment of a solar cell module according to the invention shown in FIGS. 2 and 2A differs from the first exemplary embodiment in that the carrier element 3a of the second exemplary embodiment has curvatures in two directions perpendicular to one another:

According to the illustration in FIG. 2A, the carrier element 3a has a uniform curvature having radius of curvature 2000 mm in the direction A and a uniform curvature having radius of curvature 1500 mm in the direction B.

Each solar cell 2 is in turn assigned a solar cell normal vector, which is perpendicular to the surface of the solar cell and the vectorial mean value of the solar cell normal vectors results in the solar cell module normal vector, which is perpendicular to the plane of the drawing in the illustration of FIGS. 2 and 2A.

In FIG. 2A, the tilt angle is indicated for each solar cell, which results as the angle between the solar cell normal vector of the solar cell and the solar cell module normal vector.

As is furthermore apparent in FIG. 2A, the second exemplary embodiment has five module segments. Four further module segments 1b, 1c, 1d, and 1e are arranged around a first module segment 1a. As is apparent in FIG. 2, each of the four module segments has six solar cells, which are interconnected in series.

It is apparent from FIG. 2A that a tilt angle range of 3º to 5° is assigned to the first module segment 1a, whereas the module segments 1b, 1c, 1d, and 1e are each assigned a tilt angle range of 10° to 20°. Therefore, two disjoint tilt angle ranges are provided. The angle span for module segment 1a is therefore 2° and it is 10° for each of the module segments 1b, 1c, 1d, and 1e.

The solar cell module according to the second exemplary embodiment shown in FIG. 2 therefore has four module segments 1b, 1c, 1d, and 1e which surround a center module segment, the first module segment 1a.

The advantage results in this way that the solar cells in the center area of the module, which have relatively small tilt angles, because they are close to the apex of the curve, are grouped in one segment. The maximum difference of the tilt angle range of the segments having large tilt angles is thus reduced, by which the yield of the module is increased.

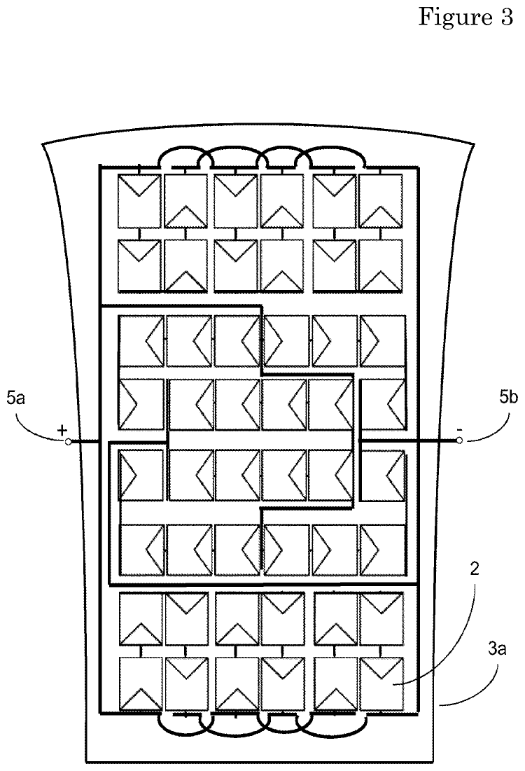

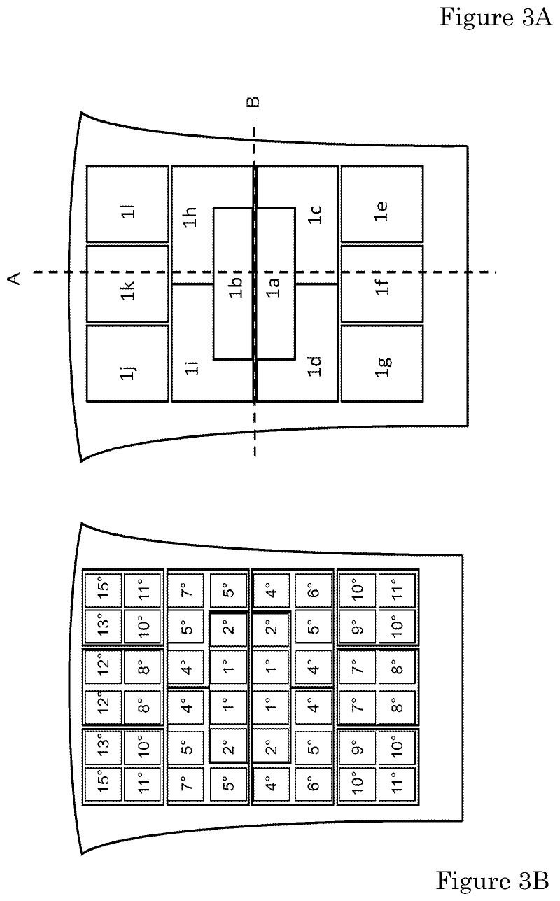

FIGS. 3 and 3A show a third exemplary embodiment of a solar cell module according to the invention, which is a refinement of the second exemplary embodiment shown in FIGS. 2 and 2A. Only the significant differences will be discussed hereinafter to avoid repetitions.

The carrier element 3a of the third exemplary embodiment has different radii of curvature in the direction A and in the direction B.

However, the solar cell module of the third exemplary embodiment has 10 module segments 1a to 1l. Each of the module segments has four solar cells 2 connected in series. Two center module segments 1a and 1b are surrounded by a group of four module segments 1c, 1d, 1e, and 1f. In addition, three square module segments 1g, 1h, and 1i as well as 1j, 1k and 1l are arranged in each case at the upper and lower edge according to the illustration in FIGS. 3 and 3a.

As is apparent in FIG. 3, all module segments are interconnected in parallel.

The tilt angle is indicated in FIG. 3B, for each solar cell 2 of the module segment according to the third exemplary embodiment. The following tilt angle ranges for the module segments result in this way:

| Segment | Angle range |
|---|---|
| 1a | 0-2° |
| 1b | 0-2° |
| 1c | 4-6° |
| 1d | 4-6° |
| 1e | 9-11° |
| 1f | 7-8° |
| 1g | 9-11° |
| 1h | 4-7° |
| 1i | 4-7° |
| 1j | 10-15° |
| 1k | 8-12° |
| 1l | 10-15° |

This division results in the advantage that the angle ranges do not exceed a maximum difference of 5°. Moreover, the solar cells have a similar orientation in relation to the sun in the segments.

### LIST OF REFERENCE SIGNS

1a first module segment
1b second module segment
1c third module segment
1e to 1l module segments
2 solar cell
3, 3a carrier element
4 solar cell module normal vector
5a, 5b connection poles

1. A solar cell module, comprising:
at least one first, one second, and one third module segment (1a, 1b, 1c), each of the module segments (1a-1l) having a plurality of photovoltaic solar cells (2) interconnected in series;
the solar cells (2) of the module segments (1a-1l) are arranged on or in a curved planar carrier element (3, 3a);
each of the solar cells is assigned a solar cell normal vector, the solar cell module is assigned a solar cell module normal vector (4), which corresponds to a vectorial mean value of the solar cell normal vectors;
each of the solar cells (2) is assigned a tilt angle, which corresponds to an angle between the solar cell normal vector of the solar cell (2) and the solar cell module normal vector (4);
each of the module segments is assigned a tilt angle range, limits of which are defined by minimum and maximum tilt angles of the solar cells (2) of the module segment (1a-1l);
tilt angle ranges of at least two of the module segments (1a-1l) are disjoint;
the module segments (1a-1l) are interconnected in parallel;
ach of the module segment (1a-1l) has a same number of solar cells (2); and
each of the solar cells (2) of each said module segment (1a-1l) is arranged directly adjacent to at least one further one of the solar cells (2) of the same module segment (1a-1l).

2. The solar cell module as claimed in claim 1, wherein the solar cell module has at least 5 of the module segments (1a-1l).

3. The solar cell module as claimed in claim 1, wherein the solar cell module has at least 3, in of the module segments (1a-1l) having disjoint angle ranges.

4. The solar cell module as claimed in claim 1, wherein all module segments (1a-1l) of the solar cell module have a same number of the solar cells (2).

5. The solar cell module as claimed in claim 1, wherein the solar cells (2) of each said module segment (1a-1l) are interconnected in series.

6. The solar cell module as claimed in claim 1, wherein the solar cell module has at least one of the module segments (1c, 1d, 1i, 1h), which adjoins an adjacent one of the module segments on two sides.

7. The solar cell module as claimed in claim 6, wherein the solar cell module has a group of at least two of the module segments (1c, 1d, 1i, 1h), which surround at least one center one of the module segment (1a, 1b).

8. The solar cell module as claimed in claim 1, wherein the solar cells (2) of the solar cell module comprise solar cells that are contactable on a rear side.

9. The solar cell module as claimed in claim 1, wherein the solar cell module has at least one of the module segments (1c, 1d, 1i, 1h), which surrounds at least one corner of an adjacent one of the module segments.
